(19) United States
(12) Patent Application Publication
(10) Pub. No.: US 2025/0089327 A1
(43) Pub. Date: Mar. 13, 2025

(54) LOW EXTERNAL RESISTANCE LAST NANOSHEET

(71) Applicant: International Business Machines Corporation, Armonk, NY (US)

(72) Inventors: Effendi Leobandung, Stormville, NY (US); Shogo Mochizuki, Mechanicville, NY (US); Andrew M. Greene, Slingerlands, NY (US); Gen Tsutsui, Glenmont, NY (US)

(21) Appl. No.: 18/462,716

(22) Filed: Sep. 7, 2023

(51) Int. Cl. H01L 29/66; H01L 21/02; H01L 21/8234; H01L 27/088; H01L 29/06; H01L 29/423; H01L 29/775; H01L 29/786

(52) U.S. Cl. CPC H10D 64/017; H01L 21/02532; H10D 30/014; H10D 30/43; H10D 30/6735; H10D 30/6757; H10D 62/121; H10D 64/018; H10D 84/0128; H10D 84/013; H10D 84/038; H10D 84/83

(57) ABSTRACT

A semiconductor structure includes a semiconductor structure. The semiconductor structure may include a semiconductor structure. The semiconductor structure may include a first gate with nanosheet layers of high-K metal gate (HKMG) and gate channel, a second gate with nanosheet layers of HKMG and gate channel, a source/drain (S/D) channel having a single continuous material between the first gate and the second gate, and inner spacers between the HKMG and the S/D channel.

### BACKGROUND

The present disclosure generally relates to fabrication methods and resulting structures for semiconductor structures, and more particularly, to a low-external resistance, continuous material source/drain channel.

Nanosheet transistors work based on the same fundamental principles as traditional field-effect transistors (FETs). The primary components of a nanosheet transistor include the nanosheet channel, the gate electrode, and the source and drain regions. The nanosheet channel is a thin layer of semiconductor material that determines the path through which electrical current flows between the source and drain regions. The gate electrode is a metal layer separated from the nanosheet channel by a thin insulating dielectric layer. By applying a voltage to the gate electrode, an electric field is created in the channel region, controlling the flow of current through the nanosheet.

By varying the gate voltage, the nanosheet transistor can be switched between the on-state and off-state. This switching action controls the flow of current through the transistor, enabling the transistor to amplify and switch electronic signals, making the transistor a fundamental building block of digital logic circuits. Nanosheet transistors have the advantage of improved electrostatic control and reduced short-channel effects compared to traditional planar transistors. This allows for better scalability and performance, making nanosheet transistors a promising candidate for future high-performance and energy-efficient semiconductor devices. As technology continues to advance, nanosheet transistors may play a vital role in the next generation of integrated circuits and electronic devices.

### SUMMARY

In one embodiment, the present invention may include a semiconductor structure. The semiconductor structure may include a first gate with nanosheet layers of high-K metal gate (HKMG) and gate channel, a second gate including nanosheet layers of HKMG and gate channel, a source/drain (S/D) channel including a single continuous material between the first gate and the second gate, and inner spacers between the HKMG and the S/D channel.

In one embodiment, the present invention may include, a method of forming a semiconductor structure. The method may include growing buffer silicon on lateral sides of a first dummy gate and a second dummy gate. The dummy gates may include inner spacers and nanosheet layers including alternating SiGe dummy layers, and silicon layers. The method may also include growing a source/drain (S/D) epi on the buffer silicon, annealing the S/D epi and the buffer silicon into a single continuous material, and replacing the SiGe dummy layers with a high-K metal gate (HKMG).

In one embodiment, the present invention may include a semiconductor structure. The semiconductor structure may include a first gate with nanosheet layers of high-K metal gate (HKMG) and gate channel. The layers of gate channel may include a silicon-germanium (SiGe) material that varies in SiGe percentage along the channel. The semiconductor structure may also include a second gate including nanosheet layers of HKMG and gate channel, and a source/drain (S/D) channel between the first gate and the second gate.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 depicts a cross-sectional side view of a semiconductor structure 100, at a stage of according to an embodiment of the current invention.

FIGS. 2A and 2B depict views of the semiconductor structure at a stage of fabrication, according to an embodiment of the current invention.

FIG. 3 depicts a cross-sectional side view of the semiconductor structure at a stage of fabrication, in accordance with one embodiment of the present invention.

FIG. 4 depicts a cross-sectional side view of the semiconductor structure at a stage of fabrication, in accordance with one embodiment of the present invention.

FIG. 5 depicts a cross-sectional side view of the semiconductor structure at a stage of fabrication, in accordance with one embodiment of the present invention.

FIG. 6 depicts a cross-sectional side view of the semiconductor structure at a stage of fabrication, in accordance with one embodiment of the present invention.

FIG. 7 depicts a cross-sectional side view of the semiconductor structure at a stage of fabrication, in accordance with one embodiment of the present invention.

FIG. 8 depicts a cross-sectional side view of the semiconductor structure at a stage of fabrication, in accordance with one embodiment of the present invention.

FIG. 9 depicts a cross-sectional side view of the semiconductor structure at a stage of fabrication, in accordance with one embodiment of the present invention.

FIG. 10 depicts a cross-sectional side view of the semiconductor structure at a stage of fabrication, in accordance with one embodiment of the present invention.

FIG. 11 depicts a cross-sectional side view of the semiconductor structure at a stage of fabrication, in accordance with one embodiment of the present invention.

FIG. 12 depicts a cross-sectional side view of the semiconductor structure at a stage of fabrication, in accordance with one embodiment of the present invention.

FIG. 13 depicts a cross-sectional side view of the semiconductor structure at a stage of fabrication, in accordance with one embodiment of the present invention.

FIG. 14 depicts a cross-sectional side view of the semiconductor structure at a stage of fabrication, in accordance with one embodiment of the present invention.

FIG. 15 depicts a cross-sectional side view of the semiconductor structure at a stage of fabrication, in accordance with one embodiment of the present invention.

FIG. 16 depicts a cross-sectional side view of the semiconductor structure at a stage of fabrication, in accordance with one embodiment of the present invention.

FIG. 17 depicts a cross-sectional side view of the semiconductor structure at a stage of fabrication, in accordance with one embodiment of the present invention.

FIGS. 18A and 18B depicts views of the semiconductor structure at a stage of fabrication, in accordance with one embodiment of the present invention.

### DETAILED DESCRIPTION

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first/major surface of a chip. As used herein, the term “vertical” describes an orientation that is arranged perpendicular to the first/major surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together. Similarly, the terms “above” and/or “below” are not meant to mean that the elements are immediately above or below another element—the level of one element is merely above or below the other element. The terms “directly above” and “directly below,” however, mean that one element is directly above another element, with no intervening elements. Additionally, the terms “squarely above” and “squarely below” mean that one element is above/below another element with maximum overlap in a vertical direction. That is, as an example, a first element will have no portions that are not covered by a similarly sized (or larger) element that is squarely above the first element.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. In some embodiments, epitaxial growth and/or deposition processes can be selective to forming on semiconductor surfaces, and may or may not deposit material on other exposed surfaces, such as silicon dioxide or silicon nitride surfaces.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made, without departing from the spirit and scope defined by the claims. The description of the embodiments is not limiting. In particular, elements of the embodiments described hereinafter may be combined with elements of different embodiments.

In some embodiments, etching mask layer(s) may be provided, and the layers that are not protected thereby are removed. For example, as is understood in the art, a mask layer, sometimes referred to as a photomask, may be provided by forming a layer of photoresist material on another layer, exposing the photoresist material to a pattern of light, and developing the exposed photoresist material. An etching process, such as a reactive ion etch (RIE), may be used to form patterns (e.g., openings) by removing portions of another layer. After etching, the mask layer may be removed using a conventional plasma ashing or stripping process. Accordingly, the pattern of the mask layer facilitates the removal of another layer, such as an amorphous SiO2 layer and/or a conductive oxide diffusion barrier, for example, in areas where the mask layer has not been deposited.

For the sake of brevity, conventional techniques related to semiconductor structure and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor structures and semiconductor-based ICs are well known and so, in the interest of brevity, many conventional steps will only be mentioned briefly herein or will be omitted entirely without providing the well-known process details.

Semiconductor transistors operate by controlling a signal flow between source/drains (S/Ds) using a channel. Connections between the channels and the S/Ds can include transition materials that increase the resistance between the channel and the S/Ds. Embodiments disclosed herein include a method of etching and replacing nanosheets that enable a single continuous material between the channels and between the gates. Specifically, a thin deposition on the external surface of the channel formed before the inner spacers are deposited, and a buffer semiconductor deposited after the inner spacers are deposited enables an annealing process to result in the single continuous SiGe material. The single continuous SiGe material formed as an S/D channel lowers resistance between the channel and the S/Ds.

In an embodiment of the current invention, a semiconductor structure may include a first gate with nanosheet layers of high-K metal gate (HKMG) and gate channel, a second gate with nanosheet layers of HKMG and gate channel, a source/drain (S/D) channel with a single continuous material between the first gate and the second gate, and inner spacers between the HKMG and the S/D channel. The single continuous material reduces resistance of the semiconductor structure since the S/D channel enables a signal to pass through without transitioning between multiple materials. The single continuous material may be fabricated with a specific composition and dopant to ensure that the signal flows easily from one gate channel and into another gate channel easily and with low resistance compared to other S/D channels that utilize multiple materials.

In an embodiment, the single continuous material may include silicon-germanium (SiGe), III-V materials, gallium arsenide, or indium gallium arsenide. These materials may be included in the semiconductor structure to reduce the resistance of signals flowing through the S/D channel. In an embodiment, the single continuous material may include a dopant to decrease the resistance or to increase effectiveness of the gate. In an embodiment the layers of gate channel may include a single continuous silicon material to increase the effectiveness of the signal from the HKMG or to reduce resistance of the signal from the S/D channel.

In an embodiment of the semiconductors structure, the layers of gate channel may include a silicon-germanium (SiGe) material that varies in SiGe percentage along the gate channel. The variance may be tailored to smooth the transition from one material of the S/D channel to a second material of the gate channel. In an embodiment, the semiconductor structure may include a third gate with nanosheet layers of HKMG and gate channel, and a second S/D channel having a single continuous silicon-germanium (SiGe) material between the second gate and the third gate. The third gate and second S/D channel may increase the ability of the semiconductor structure to turn and remain “off,” and increase the speed of the semiconductor structure to turn “on.” In an embodiment the single continuous material may include silicon-germanium at a germanium percentage of 15 percent.

In an embodiment, a method may include growing buffer silicon on lateral sides of a first dummy gate and a second dummy gate. The dummy gates may include inner spacers and nanosheet layers with alternating SiGe dummy layers, and silicon layers. The dummy gates enable an eventual gate channel to be formed with a single continuous material or a variable composition along the length of the gate channel. The method may also include growing a source/drain (S/D) epi on the buffer silicon, annealing the S/D epi and the buffer silicon into a single continuous silicon-germanium (SiGe) material, and replacing the SiGe dummy layers with a high-k metal gate (HKMG).

In an embodiment, a method may further include isotropically etching the silicon layers after removing the SiGe dummy layers and before formation of the HKMG, growing an isotropic silicon around the silicon layers, and annealing the silicon layers with the isotropic silicon to form a S/D channel of a single continuous SiGe material. Etching and annealing the silicon layers provides the technical benefit of reducing resistance of the semiconductor structure since the S/D channel enables a signal to pass through without transitioning between multiple materials. The single continuous material may be fabricated with a specific composition and dopant to ensure that the signal flows easily from one gate channel and into another gate channel easily and with low resistance compared to other S/D channels that utilize multiple materials.

An embodiment of a method may also include growing a liner on the lateral sides of the first dummy gate and second dummy gate before forming the inner spacers, and removing the liner when the SiGe dummy layers are removed. The liner provides a technical benefit of adjusting the composition of the single continuous material (after annealing) and can ease a transition between one material of the S/D channel and a different material of the gate channel.

In an embodiment of a method, the steps may include etching a portion of the silicon layers to form protrusions on which the liner grows. The protrusions can provide the benefit of extra space for the liner, such that when the liner is grown over the protrusions, space is still available for other components (e.g., inner spacers). Certain embodiments of a method may include the use of isotropic silicon having a germanium percentage between 20 and 35 percent. In an embodiment of the method the buffer silicon is doped. The dopant may include boron or phosphorus to enhance the functioning of PFET type and NFET type devices. In certain embodiments, annealing the S/D epi and the buffer silicon may include annealing techniques such as laser spike anneal (LSA), millisecond anneal, or nanosecond laser anneal. These annealing types provide the benefit of targeted annealing that anneal specific components of a semiconductor structure without damage to other untargeted components.

In an embodiment of the current invention, a semiconductor structure may include a first gate with nanosheet layers of high-k metal gate (HKMG) and gate channel. The layers of gate channel may include a silicon-germanium (SiGe) material that varies in SiGe percentage along the channel. The semiconductor structure may also include a second gate with nanosheet layers of HKMG and gate channel, and a source/drain (S/D) channel between the first gate and the second gate. The varying percentage of germanium provides the technical benefit of reducing resistance of the semiconductor structure since the gate channel enables a signal to pass from a S/D channel without transitioning between multiple materials. The gate channel material may be fabricated with a specific composition and dopant to ensure that the signal flows easily from one gate channel and into another gate channel easily and with low resistance compared to other S/D channels that utilize multiple materials.

In an embodiment, a S/D channel may include a dopant to increase the effectiveness of a NFET or PFET device. In an embodiment a semiconductor structure may include a third gate with nanosheet layers of HKMG and gate channel, and a second S/D channel with a single continuous material between the second gate and the third gate. The single continuous material reduces resistance of the semiconductor structure since the S/D channel enables a signal to pass through without transitioning between multiple materials. The single continuous material may be fabricated with a specific composition and dopant to ensure that the signal flows easily from one gate channel and into another gate channel easily and with low resistance compared to other S/D channels that utilize multiple materials.

In an embodiment, the single continuous material of the S/D channels may include silicon-germanium (SiGe), III-V materials, gallium arsenide, or indium gallium arsenide. These materials provide the technical a good balancing between the benefit of semiconducting and the availability of the material for a given price. In certain embodiments, the second S/D channel may include a dopant to ensure that the signal flows easily from one gate channel and into another gate channel easily and with low resistance compared to other S/D channels that utilize multiple materials. In certain embodiments, a semiconductor structure may include inner spacers between the HKMG and the S/D channel to provide the right amount of electrical insulating between the S/D channel and the HKMG.

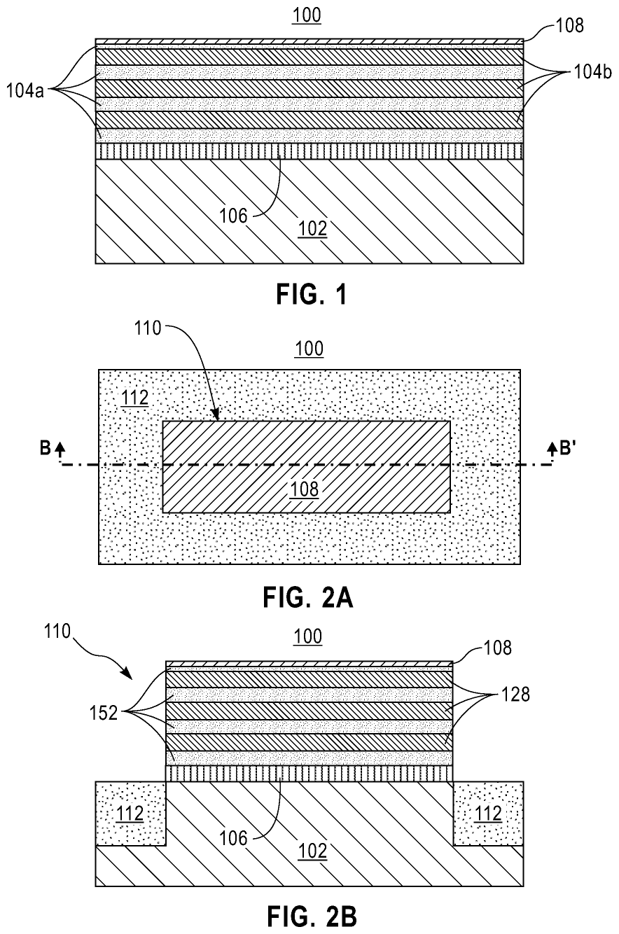

Turning now to the figures, FIG. 1 depicts a cross-sectional side view of a semiconductor structure 100, according to an embodiment of the current invention. The semiconductor structure 100 is fabricated on a substrate 102. The substrate 102 may be silicon, but other materials may also be used. Above the substrate 102, the semiconductor structure 100 includes nanosheet channels 104a,b that are separated from the substrate 102 by a sacrificial layer 106. The nanosheet channels 104a,b may be fabricated, for example, by forming epitaxial semiconductor layers sequentially above the sacrificial layer 106. The sacrificial layer 106 may include a higher germanium composition (e.g., 50% silicon/50% germanium) material that will cleanly etch from the subsequently formed nanosheet channels 104a,b. Then the layers may be epitaxially grown using alternating SiGe layers 104a (e.g., 25% germanium/75% silicon) and nanosheet channels of silicon layers 104b (100% silicon). Other methods may be used to form the silicon 104b and the SiGe layers 104a.

It is understood that the nanosheet channels 104a,b can include any number of nanosheets alternating with a corresponding number of sacrificial dummy layers. For example, the nanosheet channels 104a,b can include two nanosheets, five nanosheets, eight nanosheets, thirty nanosheets (e.g., 3D NAND), or any number of nanosheets, along with a corresponding number of sacrificial layers (i.e., as appropriate to form a nanosheet stack having a bottommost sacrificial layer under a bottommost nanosheet and a sacrificial layer between each pair of adjacent nanosheets). In some embodiments, the nanosheet channels 104a,b have a thickness of about 4 nm to about 15 nm, for example 10 nm, although other thicknesses are within the contemplated scope of the present disclosure. In some embodiments, the substrate 102 and the nanosheet channels 104a,b can be made of a same semiconductor material. In other embodiments, the substrate 102 can be made of a first semiconductor material, and the nanosheet channels 104a,b can be made of a second and/or third semiconductor material.

The semiconductor structure 100 may also include a hard mask 108 that protects the nanosheet channels 104a,b during further processes described below. The hard mask 108 may include oxide, nitride, or combinations of nitride and oxide to protect the nanosheet channels 104a,b.

FIG. 2A depicts a top-down view of the semiconductor structure 100 and FIG. 2B depicts a cross-sectional side view of the semiconductor structure 100 at a next stage in the fabrication process, according to an embodiment of the current invention. The semiconductor structure 100 has been etched into a channel 110. In the top-down view of FIG. 2A, the channel 110 is shown in a rectangular shape, which is common (but not exclusively) used in embodiments of the channel 110. To shape the channel 110 to the designed size, an etch process utilizing a photo-sensitive organic polymer may be used. Specifically, the photo-sensitive organic polymer may be made from a photo-sensitive organic polymer that is chemically altered when exposed to electromagnetic (EM) radiation. The alteration of the photo-sensitive organic polymer enables a developing solvent to remove the exposed portions. For example, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene (BCB). More generally, for example, the photo-sensitive organic polymer can include any organic polymer and a photo-active compound having a molecular structure that can attach to the molecular structure of the organic polymer. In some embodiments, the material is selected to be compatible with an overlying antireflective coating and/or an overlying photoresist. In some embodiments, the masking material can be applied using spin coating technology, although other techniques are within the contemplated scope of the present disclosure. Other components of the semiconductor structure 100 include shallow trench isolations (STI) 112 in the substrate 102 that isolate the channels 110 from other devices in the semiconductor structure 100.

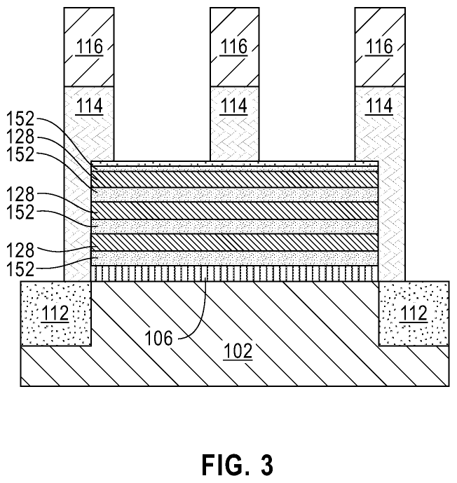

FIG. 3 depicts a cross-sectional side view (along line B-B′ indicated in FIG. 2A) of the semiconductor structure 100 at a stage of fabrication, in accordance with one embodiment of the present invention. The semiconductor structure 100 includes dummy gates 114 patterned using a dummy gate mask 116 composed of a material that may be similar to the hard mask 108 described above. The dummy gates 114 may include amorphous silicon (a-Si) and are formed using normal deposition, patterning, and etch processes to set the location for the gates which are formed later in the fabrication of the semiconductor structure 100. The illustrated embodiment includes two end dummy gates 114 and one middle dummy gate 114, but other combinations of dummy gates 114 may be used within the scope of the invention disclosed here.

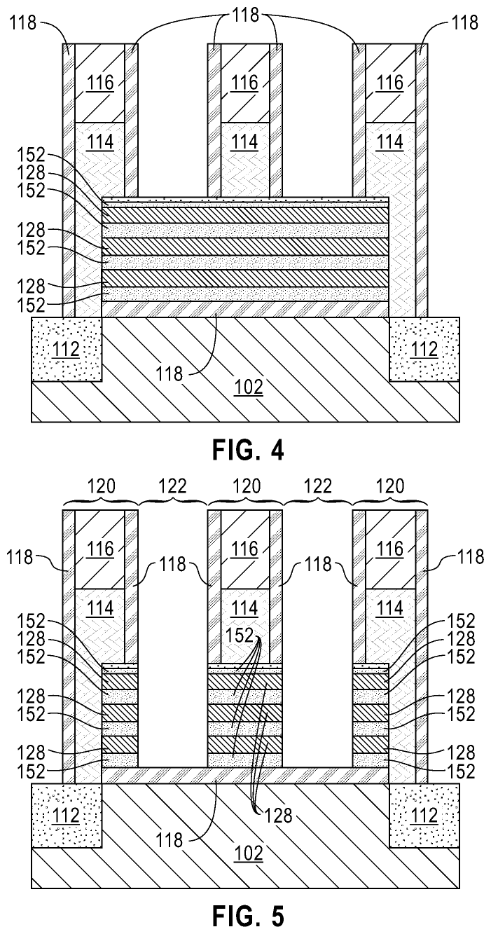

FIG. 4 depicts a cross-sectional side view of the semiconductor structure 100 at a stage of fabrication, in accordance with one embodiment of the present invention. The semiconductor structure 100 includes dummy spacers 118 surrounding the dummy gates 114 and the dummy gate masks 116. The dummy spacers 118 also replace the sacrificial layer 106. The sacrificial layer 106 may be removed using a selective etch process that does not affect the nanosheet channels 104a,b or the dummy gates 114. The sacrificial layer 106 is typically removed before the dummy spacers 118 are deposited such that a bottom dummy spacer 118a is deposited at the same time as the rest of the dummy spacers 118.

FIG. 5 depicts a cross-sectional side view of the semiconductor structure 100 at a stage of fabrication, in accordance with one embodiment of the present invention. The semiconductor structure 100 includes fins 120 formed when fin gaps 122 are etched into the channel 110 between the dummy gates 114. The fin gaps 122 may be etched using directional etch techniques such as reactive ion etch.

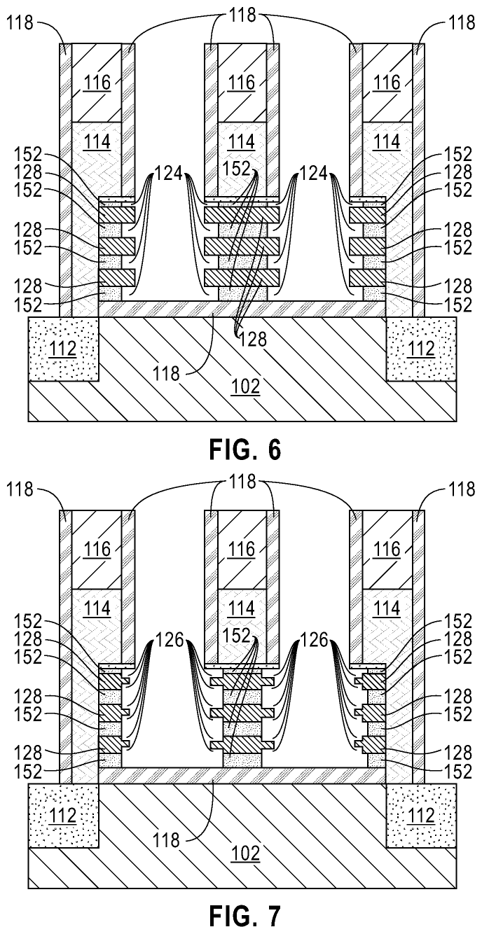

FIG. 6 depicts a cross-sectional side view of the semiconductor structure 100 at a stage of fabrication, in accordance with one embodiment of the present invention. The semiconductor structure 100 includes indents 124 that are formed by selectively etching the SiGe layers 104a laterally from the sides of the fin gaps 122 without etching the silicon layers 104b.

FIG. 7 depicts a cross-sectional side view of the semiconductor structure 100 at a stage of fabrication, in accordance with one embodiment of the present invention. The semiconductor structure 100 includes expansions 126 of the indents 124 that are formed by selectively etching the silicon layer 104b. This particular stage is optional, and any etching that is done on the silicon layers 104b is done using an isotropic etch process that does not just etch the silicon layers 104b laterally. In the illustrated embodiment for example, the silicon layers 104b are etched laterally and from top and bottom such that a protrusion 128 protrudes from the silicon layer 104b beyond the edge of the SiGe layers 104a. The protrusion 128 is useful in forming the correct size of spacers and gate channels as described below.

FIG. 8 depicts a cross-sectional side view of the semiconductor structure 100 at a stage of fabrication, in accordance with one embodiment of the present invention. The semiconductor structure 100 includes a liner 130 covering the exposed surfaces of the nanosheet channels 104a,b. The liner 130 may include heavily doped silicon or SiGe. For embodiments used for PFET devices, Boron, for example, may be used for doping. For embodiments used for NFET devices, Phosphorus, for example, may be used for doping. The purpose of the heavily doped material is to lower the resistance of the liner 130. The liner 130 may be grown over the protrusions 128 to specifically replace the expansions 126 of the indents 124. That is, if the expansions 126 are etched to take away 2 nm of the SiGe layers 104a, then the liner 130 may be tailored to fill in 2 nm so that the indents 124 are about the same original size (i.e., the thickness of the silicon layers 104b). In other embodiments, the expansions 126 and liner 130 may be different thicknesses, such that the indents 124 are larger/smaller than the silicon layers 104b.

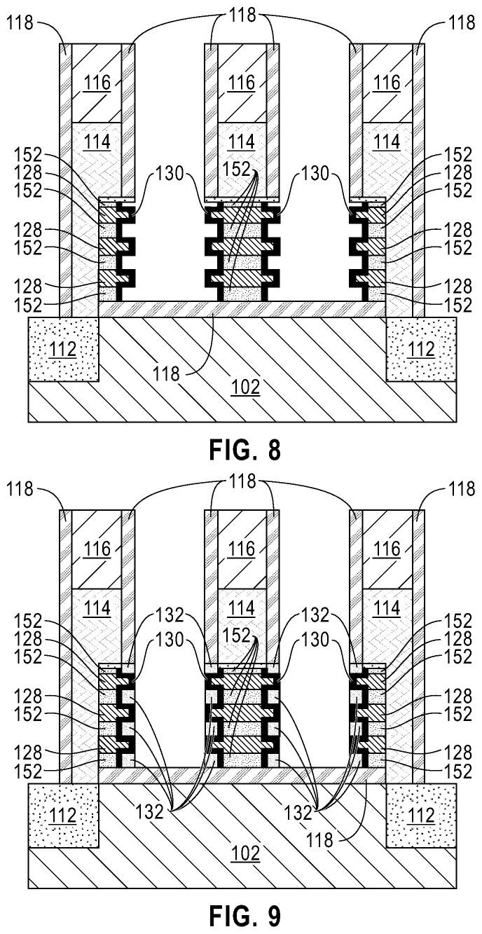

FIG. 9 depicts a cross-sectional side view of the semiconductor structure 100 at a stage of fabrication, in accordance with one embodiment of the present invention. The semiconductor structure 100 includes inner spacers 132 that are deposited within the indents 124, and subsequently etched back to be flush with the liner 130. The inner spacers 132 may include nitride based material such as silicon boron carbide nitride (SiBCN), SiOCN, SiN, SiOC, etc. or other non-nitride based masking materials.

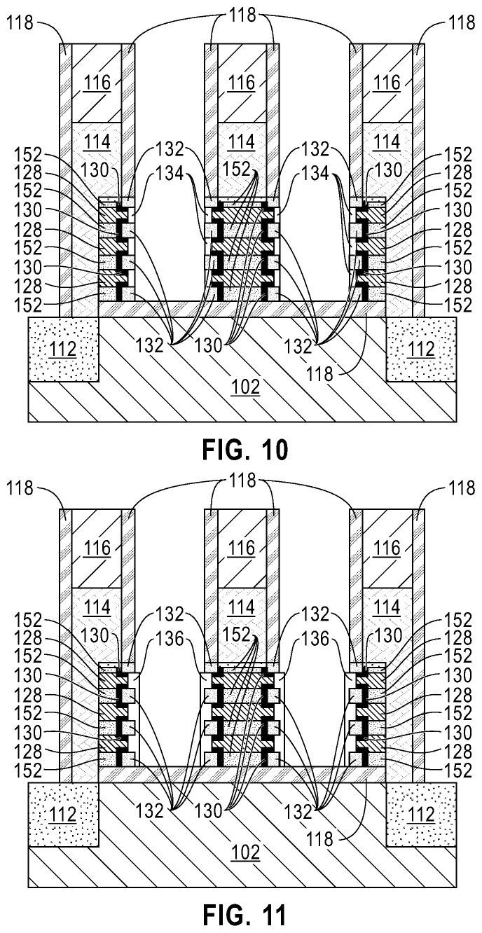

FIG. 10 depicts a cross-sectional side view of the semiconductor structure 100 at a stage of fabrication, in accordance with one embodiment of the present invention. The semiconductor structure 100 includes liner removal holes 134 formed by selectively etching the liner 130 from between the inner spacers 132. This etching of the liner 130 exposes the tip of the protrusions 128. The liner removal holes 134 create extra surface area around the inner spacers 132 which aids in the formation of the source/drain (S/D) channel described above and shown in the final figures below. This step is optional depending on type of material grown in liner 130.

FIG. 11 depicts a cross-sectional side view of the semiconductor structure 100 at a stage of fabrication, in accordance with one embodiment of the present invention. The semiconductor structure 100 includes a buffer silicon 136 grown on the lateral sides of the fins 120. The buffer silicon 136 is selectively deposited on the inner spacers 132, liner 130, and protrusions 128 without deposition on the dummy spacers 118. The buffer silicon 136 may be doped, for example with boron for PFET and Phosphorus for NFET, to increase the doping of the S/D channel eventually formed between the gates (i.e., gates will replace the dummy gates 114 shown here in FIG. 11). The doping of the buffer silicon 136 may be variable (i.e., different doping levels within the buffer silicon 136), and in certain embodiments the buffer silicon 136 may include high doping amounts or undoped silicon.

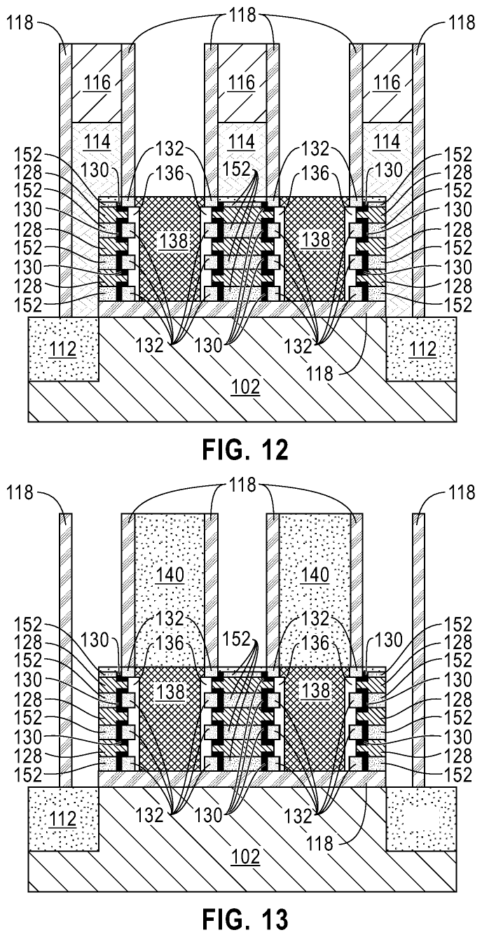

FIG. 12 depicts a cross-sectional side view of the semiconductor structure 100 at a stage of fabrication, in accordance with one embodiment of the present invention. The semiconductor structure 100 includes a S/D epi 138 grown between the buffer silicon 136 within the fin gaps 122. The S/D epi 138 is grown only to the top of the nanosheet channels 104a,b, and may be grown flat to ensure uniformity between all the S/D epis 138. The S/D epi 138 may also be doped (e.g., with boron for PFET and Phosphorus for NFET), and may be annealed using a laser spike annealing process that avoids heating within the gate region (i.e., the nanosheet channels 104a,b, inner spacers 132, liner 130, etc.).

FIG. 13 depicts a cross-sectional side view of the semiconductor structure 100 at a stage of fabrication, in accordance with one embodiment of the present invention. The semiconductor structure 100 includes a fill-in insulator 140 that is deposited between the dummy spacers 118 above the S/D epi 138. The fill-in insulator 140 may include oxide, nitride, or other insulating material to electrically isolate the S/D epi 138 (and the eventual S/D channel) from signals flowing through signal channels above the semiconductor structure 100. After the fill-in insulator 140 is deposited, the dummy gates 114 and dummy gate masks 116 may be removed using a selective etch process. The dummy spacers 118 may remain in place around the fill-in insulator 140 and defining the gate region on the end of the semiconductor structure 100.

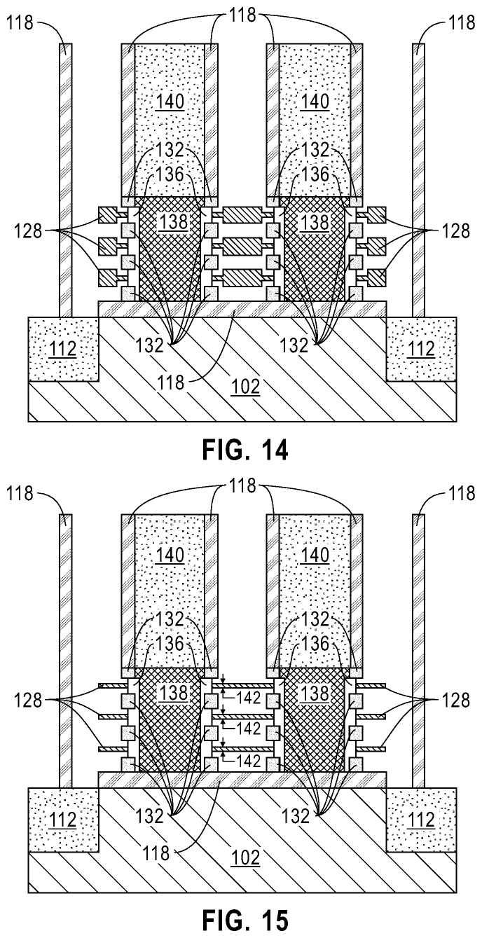

FIG. 14 depicts a cross-sectional side view of the semiconductor structure 100 at a stage of fabrication, in accordance with one embodiment of the present invention. The semiconductor structure 100 includes a removal of the SiGe layers 104a from between the silicon layers 104b. Removing the SiGe layers 104a may also include removing the hard mask 108 and the liner 130 such that the silicon layers 104b, the inner spacers 132, and the buffer silicon 136 are exposed to the gate region of the semiconductor structure 100. With the liner 130 and SiGe layers 104a removed, the silicon layers 104b are attached to the buffer silicon 136 and the S/D epi 138 only by the protrusions 128.

FIG. 15 depicts a cross-sectional side view of the semiconductor structure 100 at a stage of fabrication, in accordance with one embodiment of the present invention. The semiconductor structure 100 includes the silicon layers 104b etched and thinned so that a thickness 142 of the silicon layers 104b is uniform across the width of the gate region. In other words, the thickness 142 of the whole of the silicon layers 104b is the same as the thickness of the protrusions 128. The thinning of the silicon layers 104b, in certain embodiments, may be less than the thinning shown in FIG. 15. For example, the thickness 142 of the silicon layers 104b may be less than the thickness of the protrusions 128. Furthermore, the thickness 142 of the silicon layers 104b may be controlled to be a specific measurement smaller than the original silicon layers 104b. For example, the thickness 142 may be 2 nm smaller than the original silicon layers 104b.

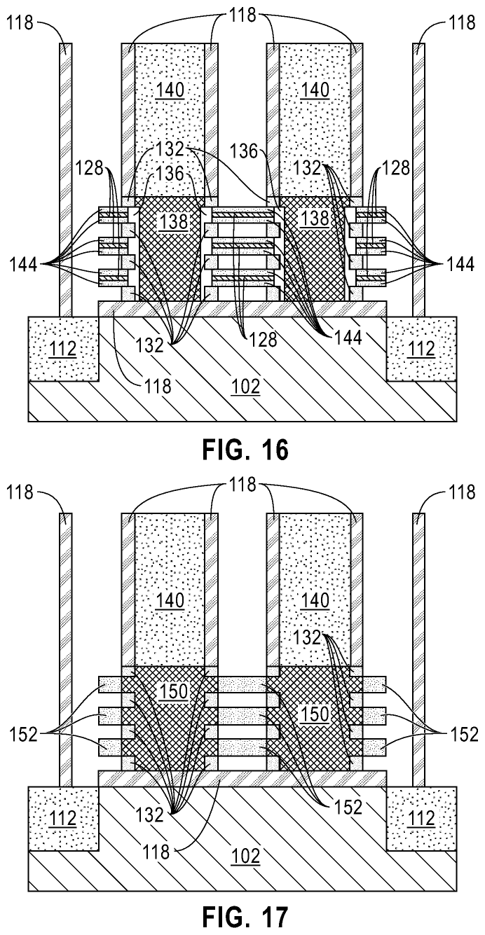

FIG. 16 depicts a cross-sectional side view of the semiconductor structure 100 at a stage of fabrication, in accordance with one embodiment of the present invention. The semiconductor structure 100 includes isotropic silicon 144 grown around the silicon layers 104b. The isotropic silicon 144 is grown around the thinned portion of the silicon layers 104b, and is also grown in the space adjacent to the buffer silicon 136 between the inner spacers 132. The growth of the isotropic silicon 144 may be tailored in design to replace the thinning of the silicon layers 104b that was shown in FIG. 15. Specifically, if the thickness 142 is 2 nm smaller that the original silicon layers 104b, the isotropic silicon 144 may be grown 2 nm thick to make the combination of silicon layers 104b and isotropic silicon 144 to be the same as the original silicon layers 104b. The isotropic silicon 144 may be similar in composition to the silicon layers 104b. For example, the isotropic silicon 144 and silicon layers 104b may include pure silicon with no dopants. In certain embodiments, the isotropic silicon 144 and silicon layers 104b may include a amount of germanium or other dopant. In certain embodiments, the isotropic silicon 144 may contain a percentage of Ge (20-35% undoped SiGe) while the silicon layers 104b do not contain Ge. In certain embodiments, the isotropic silicon 144 may contain no other material while the silicon layers 104b do contain other material.

FIG. 17 depicts a cross-sectional side view of the semiconductor structure 100 at a stage of fabrication, in accordance with one embodiment of the present invention. The semiconductor structure 100 includes thermally annealed S/D channels 150 and gate channels 152. The S/D channels 150 convert the S/D epis 138 and buffer silicon 136 into a single continuous SiGe material that reduces resistance in signals propagating between gates. The gate channels 152 are also converted, through the annealing process, into a single continuous structure. The benefits of these single continuous structures is clear with the finished structure illustrated below.

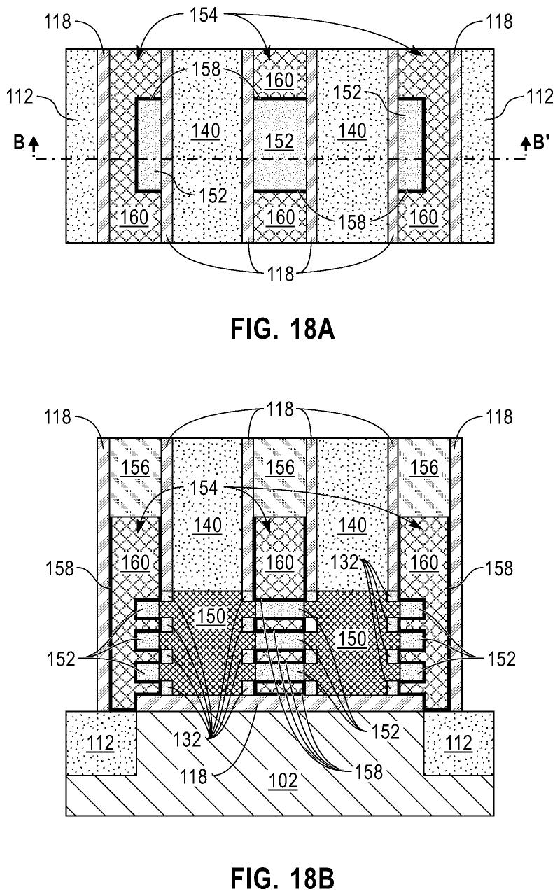

FIGS. 18A and 18B depicts views of the semiconductor structure 100 at a stage of fabrication, in accordance with one embodiment of the present invention. FIG. 18A depicts a cross-sectional top view, and FIG. 18B depicts a cross-sectional side view of the semiconductor structure 100. The semiconductor structure 100 includes gates 148a, b, c made up of layers of high-K metal gate (HKMG) 154 and the gate channels 152. The HKMG 154 includes a HK liner 158 formed around the gate channels 152, with a metal gate 160 filling all the remaining space in the gate region. The semiconductor structure 100 also includes a gate cap 156 made of suitable dielectric material, such as, for example, oxides, a low-k dielectric, nitrides, silicon nitride, silicon oxide, SiON, SiC, SiOCN, and/or SiBCN.

In operation, the semiconductor structure 100 enables signal flow from the S/D channels 150 through the gate channels 152 based on a gate signal applied to the HKMG 154 of each gate 148a, b, c. As the signal travels through the gate channels 152, electrons in the single continuous SiGe material of the S/D channels 150 enable a lower resistance relative to structures that have multiple structures and materials between the S/Ds and the gates.

In one aspect, the method and structures as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections and buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

The descriptions of the various embodiments of the present teachings have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Importantly, although the operational/functional descriptions described herein may be understandable by the human mind, they are not abstract ideas of the operations/functions divorced from computational implementation of those operations/functions. Rather, the operations/functions represent a specification for an appropriately configured computing device. As discussed in detail above, the operational/functional language is to be read in its proper technological context, i.e., as concrete specifications for physical implementations.

Accordingly, one or more of the methodologies discussed herein may obviate a need for time consuming data processing by the user. This may have the technical effect of reducing computing resources used by one or more devices within the system. Examples of such computing resources include, without limitation, processor cycles, network traffic, memory usage, storage space, and power consumption.

It should be appreciated that aspects of the teachings herein are beyond the capability of a human mind. It should also be appreciated that the various embodiments of the subject disclosure described herein can include information that is impossible to obtain manually by an entity, such as a human user. For example, the type, amount, and/or variety of information included in performing the process discussed herein can be more complex than information that could be reasonably be processed manually by a human user.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features and objects that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. An element proceeded by “a” or “an” does not, without further constraints, preclude the existence of additional identical elements in the process, method, article, or apparatus that comprises the element.

What is claimed is:

1. A semiconductor structure comprising:
a first gate comprising nanosheet layers of high-K metal gate (HKMG) and gate channel;
a second gate comprising nanosheet layers of HKMG and gate channel;
a source/drain (S/D) channel comprising a single continuous material between the first gate and the second gate; and
inner spacers between the HKMG and the S/D channel.

2. The semiconductor structure of claim 1, wherein the single continuous material comprises a selection from the group consisting of: silicon-germanium (SiGe), III-V materials, gallium arsenide, and indium gallium arsenide.

3. The semiconductor structure of claim 1, wherein the single continuous material comprises a dopant.

4. The semiconductor structure of claim 1, wherein the layers of gate channel comprise a single continuous silicon material.

5. The semiconductor structure of claim 1, wherein the layers of gate channel comprise a silicon-germanium (SiGe) material that varies in SiGe percentage along the gate channel.

6. The semiconductor structure of claim 1, further comprising:
a third gate comprising nanosheet layers of HKMG and gate channel; and
a second S/D channel comprising a single continuous silicon-germanium (SiGe) material between the second gate and the third gate.

7. The semiconductor structure of claim 1, wherein the single continuous material comprises silicon-germanium at a germanium percentage of 15 percent.

8. A method, comprising:
growing buffer silicon on lateral sides of a first dummy gate and a second dummy gate, wherein the dummy gates comprise inner spacers and nanosheet layers comprising alternating SiGe dummy layers, and silicon layers;
growing a source/drain (S/D) epi on the buffer silicon;
annealing the S/D epi and the buffer silicon into a single continuous material; and
replacing the SiGe dummy layers with a high-K metal gate (HKMG).

9. The method of claim 8, further comprising:
isotropically etching the silicon layers after removing the SiGe dummy layers and before formation of the HKMG;
growing an isotropic silicon around the silicon layers; and
annealing the silicon layers with the isotropic silicon to form an S/D channel of a single continuous SiGe material.

10. The method of claim 9, further comprising:
growing a liner on the lateral sides of the first dummy gate and second dummy gate before forming the inner spacers; and
removing the liner when the SiGe dummy layers are removed.

11. The method of claim 10, further comprising etching a portion of the silicon layers to form protrusions on which the liner grows.

12. The method of claim 9, wherein the isotropic silicon comprises a germanium percentage between 20 and 35 percent.

13. The method of claim 10, wherein the buffer silicon is doped with a selection from the group consisting of: boron and phosphorus.

14. The method of claim 10, wherein annealing the S/D epi and the buffer silicon comprises a selection from the group consisting of laser spike anneal (LSA), millisecond anneal, or nanosecond laser anneal.

15. A semiconductor structure, comprising:
a first gate comprising nanosheet layers of high-K metal gate (HKMG) and gate channel, wherein the layers of gate channel comprise a silicon-germanium (SiGe) material that varies in SiGe percentage along the channel;
a second gate comprising nanosheet layers of HKMG and gate channel; and
a source/drain (S/D) channel between the first gate and the second gate.

16. The semiconductor structure of claim 15, wherein the S/D channel comprises a dopant.

17. The semiconductor structure of claim 15, further comprising:
a third gate comprising nanosheet layers of HKMG and gate channel; and
a second S/D channel comprising a single continuous material between the second gate and the third gate.

18. The semiconductor structure of claim 17, wherein the single continuous material comprises a selection from the group consisting of: silicon-germanium (SiGe), III-V materials, gallium arsenide, and indium gallium arsenide.

19. The semiconductor structure of claim 17, wherein the second S/D channel comprises a dopant.

20. The semiconductor structure of claim 15, further comprising inner spacers between the HKMG and the S/D channel.
